(19) United States
(12) Patent Application Publication
(10) Pub. No.: US 2006/0139665 A1
(43) Pub. Date: Jun. 29, 2006

(54) System and method for printing color samples to match a target color

(75) Inventor: Raymond E. Clark, Georgetown, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(73) Assignee: Lexmark International, Inc.

(21) Appl. No.: 11/022,994

(22) Filed: Dec. 27, 2004

(51) Int. Cl. G03F 3/08

(52) U.S. Cl. 358/1.9; 358/518

(57) ABSTRACT

A system for printing color samples in a desired color space to match a user selected target color includes a printer including a controller configured to generate instructions for printing a first set of color samples such that the samples in the first set have a first color spacing and define a first volume in the color space. The controller generates instructions for printing a subsequent set of color samples according to user selections. User selections including a closest match to the target color are communicated to the controller, and the printer prints a subsequent set of color samples according to the user selections until an acceptable match to the target color is achieved.

### FIELD OF THE INVENTION

The present invention relates generally to a system for printing sets of color samples, wherein the color spacing of the samples in each set is different, in order for a user to acceptably match a target color.

### BACKGROUND OF THE INVENTION

In many instances, it is desirable to match the color of a printed object to a particular target color. For example, the color of an object that is created on a computer may be perceived differently when viewed on the computer monitor as compared to viewing it as a printed image. Similarly, the color of an object may be perceived differently when an image of the object is printed by a first process such as printing on a sheet of paper using an inkjet printer as compared to printing it by another process such as printing on a glossy web using a gravure press. It may also be desirable to match a printed image of an object to the color of an actual object.

An image, such as a logo, is often created and displayed on a computer monitor prior to being printed. On a computer monitor, an additive process of mixing appropriate amounts of red, green and blue light creates the colors of the image that is displayed. On the other hand, a subtractive process essentially creates colors printed on a print medium such as paper. In particular, color printers, such as inkjet printers, typically print using ink colors such as cyan, magenta, yellow and black. The ink on the paper absorbs (subtracts) light according to its color such that the light reflected from the ink determines the color perceived by a viewer. For example, cyan ink appears cyan because it absorbs red light and reflects green and blue light. An ink jet printer is usually able to reproduce most color combinations in an RGB (red, green, blue) color space using just cyan, magenta, and yellow ink. However, the reproduction of some colors in a color space requires the addition of black ink. Also, the RGB color space does not exactly correspond to the CMYK (cyan, magenta, yellow, black) color space. In any event, reproducing a target color displayed on one medium using a printer is potentially problematic.

### SUMMARY OF THE INVENTION

A system and method are described for printing color samples in a desired color space to match a user selected target color. The system includes a printer for printing sets of color samples. The printer includes a controller configured to generate instructions for printing a first set of color samples such that the samples in the first set have a first color spacing from one another and define a first volume in the color space. The controller also generates instructions for printing a subsequent set of color samples according to user selections. The system includes a user interface for communicating user selections to the printer, wherein the user selections include a closest match to the target color selected from a prior set of printed color samples and a desired color spacing of samples in a subsequent set. The printer prints a subsequent set of color samples according to the user selections until an acceptable match to the target color is achieved. The color levels corresponding to the acceptable match can be stored.

Other features and advantages of the invention will become apparent to those skilled in the art upon review of the following detailed description, claims, and drawings.

### BRIEF DESCRIPTION OF THE DRAWINGS

FIG. 1 illustrates one embodiment of a system for matching a color sample to a target color;

FIG. 2 illustrates one embodiment of a method for matching a color sample to a target color for the system illustrated in FIG. 1;

FIG. 3 is one example of a first set of color samples produced in accordance with the method illustrated in FIG. 2; and

FIG. 4 is one example of a second set of color samples produced in accordance with the method illustrated in FIG. 2.

### DETAILED DESCRIPTION OF THE PREFERED EMBODIMENTS

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use herein of “including,” “comprising” or “having” and variations thereof is meant to encompass the items listed thereafter and equivalents thereof as well as additional items. The terms “mounted,” “connected” and “coupled” are used broadly and encompass both direct and indirect mounting, connecting and coupling. Further, “connected” and “coupled” are not restricted to physical or mechanical connections or couplings and can include electrical connections or couplings, whether direct or indirect. The order of limitations specified in any method claims does not imply that the steps or acts set forth therein must be performed in that order, unless an order is explicitly set forth in the specification.

In addition, it should be understood that embodiments of the invention include both hardware and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the invention may be implemented in software. As such, it should be noted that a plurality of hardware and software-based devices, as well as a plurality of different structural components may be utilized to implement the invention. Furthermore, and as described in subsequent paragraphs, the specific mechanical configurations illustrated in the drawings are intended to exemplify embodiments of the invention and that other alternative mechanical configurations are possible.

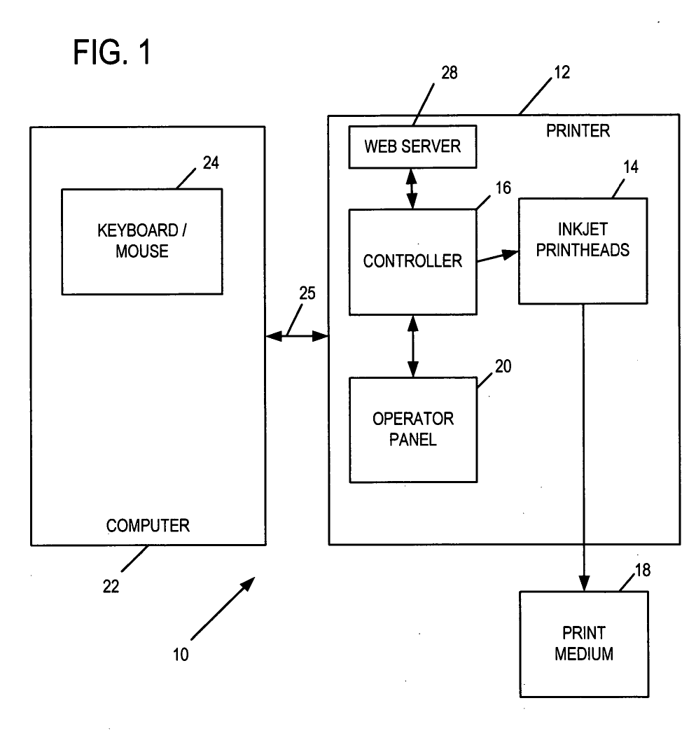

FIG. 1 illustrates one embodiment of a system 10 for printing color samples in a desired color space to match a user selected target color. The system 10 includes a printer 12, such as an inkjet or laser color printer, for printing sets of color samples. Printer 12 can be a stand-alone printer or part of a multi-function device which performs additional functions such as scanning, faxing, or copying, in addition to printing. In the illustrated embodiment, printer 12 includes inkjet printheads 14 for printing with cyan, magenta, yellow and black ink and also includes a controller 16. The controller 16 is configured to generate instructions for printing the sets of color samples onto a print medium 18, such as a sheet of paper. The system also includes a user interface for communicating user selections to the printer. In one embodiment, the operator panel 20 may operate as a user interface while in another embodiment, the user interface of a computer 22 connected to the printer 12, such as a keyboard/mouse 24 or the like, may operate as the user interface.

In such a case, for example, the printer 12 may include a web server 28. The computer 22, connected to the printer 12 via a network 25, can access and display web pages from web server 28. These web pages are displayed on the computer 22 and can include user-friendly dialog for selecting and/or inputting desired user selections, as further described below.

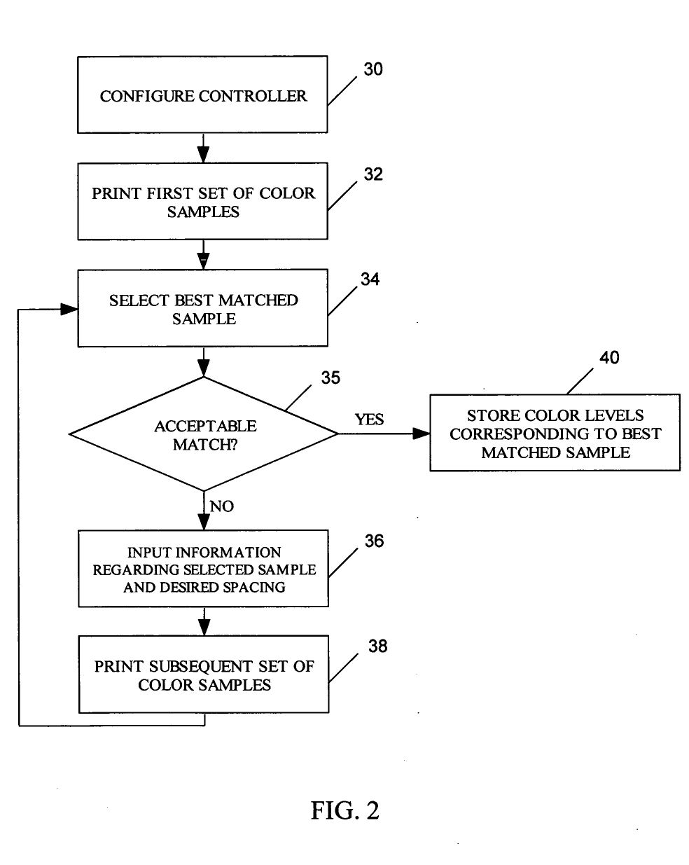

FIG. 2 illustrates one embodiment of a method for matching a color sample to a target color. Specifically, as more fully explained below, at step 30 the controller is configured to control the printing of sets of color samples taking into account user selections. At step 32, a first set of color samples is printed. At step 34, a user selects the best-matched sample to the target color from the first set of color samples. At step 35, a user decides if the selected sample is an acceptable match. If not, processing proceeds to step 36. If the selected sample is an acceptable match at step 35, then at step 40, the printer color levels corresponding to the best-matched sample can be stored. At step 36, the user inputs information to the printer via the user interface regarding the selected sample and the desired color spacing of a second set of color samples. At step 38, a second set of color samples is printed with the desired color spacing around the selected sample, and processing proceeds from there back to step 34. Again at step 34, a user selects the best-matched sample to the target color from the second (or subsequent) set of samples.

In particular, in the embodiment described, the RGB color space is used such that at step 30, the controller is configured such that it includes a printer profile for converting RGB values into CMYK printer color values. Other color spaces for the color samples could also be selected, such as a CMYK color space. Other color spaces would require different profiles for converting values in that color space into printer color values.

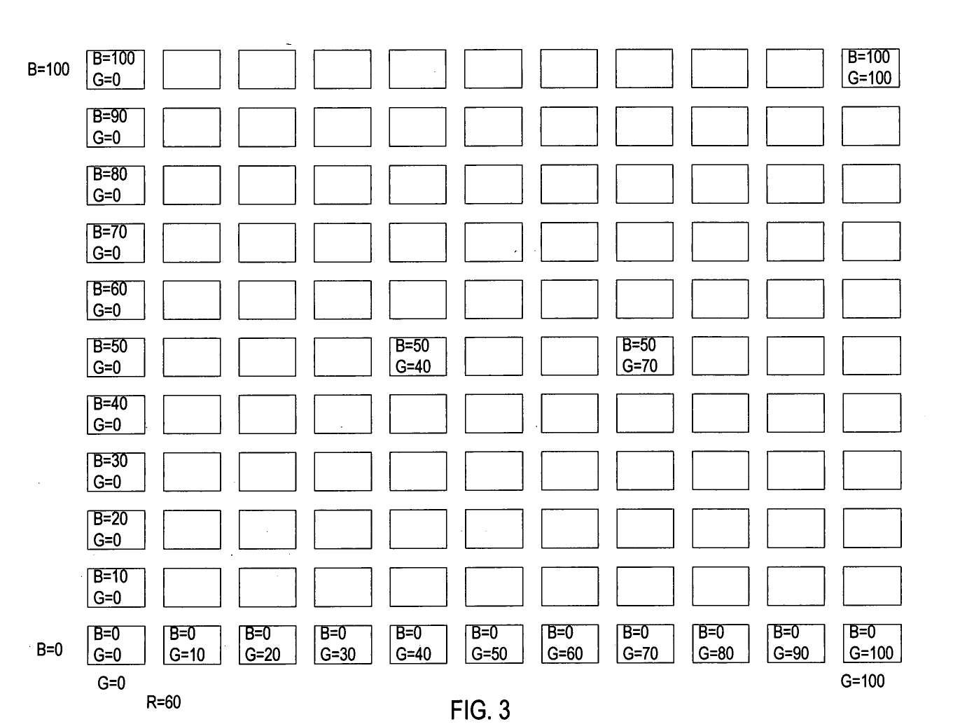

At step 32, the controller 16 generates instructions for printing a first set of color samples such that the samples in the first set have a first spacing from one another and define a first volume in the selected RGB color space. In one embodiment, the first set of color samples essentially spans this color space and samples each color at 10% increments such that the samples are equally spaced in the color space and from one another. A portion of such a first set of color samples is schematically illustrated in FIG. 3. In particular, the color samples illustrated in FIG. 3 represent points in a plane of the RGB color space, wherein the plane has a fixed red component of 60%, and the green and blue components are each varied as shown from 0% to 100%. The entire first set of color samples in this example would then include ten other portions similar to that illustrated in FIG. 3, wherein each other portion would have a different red component amount. For example, each portion could be printed on a separate sheet of paper, with separate sheets having respective red component amounts of 0%, 10%, 20%, 30%, 40%, 50%, 70%, 80%, 90%, and 100%.

Once the user selects the best matched color sample to a desired color at step 34, the information is input to the printer, using either the operator panel 20, or the user interface of the computer 22 at step 36. As discussed, the user can access and display web pages from the web server 28 of the printer 12 on the computer 22. The web pages provide a user interactive display such that the user knows what information is required and can enter that information. In particular, the user can enter information regarding a selected best matched color sample and a desired color spacing of a new set of color samples.

The desired color spacing can either be a default value of perhaps 1% for all colors, or another amount chosen by the user. The controller 16 then generates instructions for printing subsequent sets of color samples according to these user selections, and these sets are printed by the printer 12 at step 38.

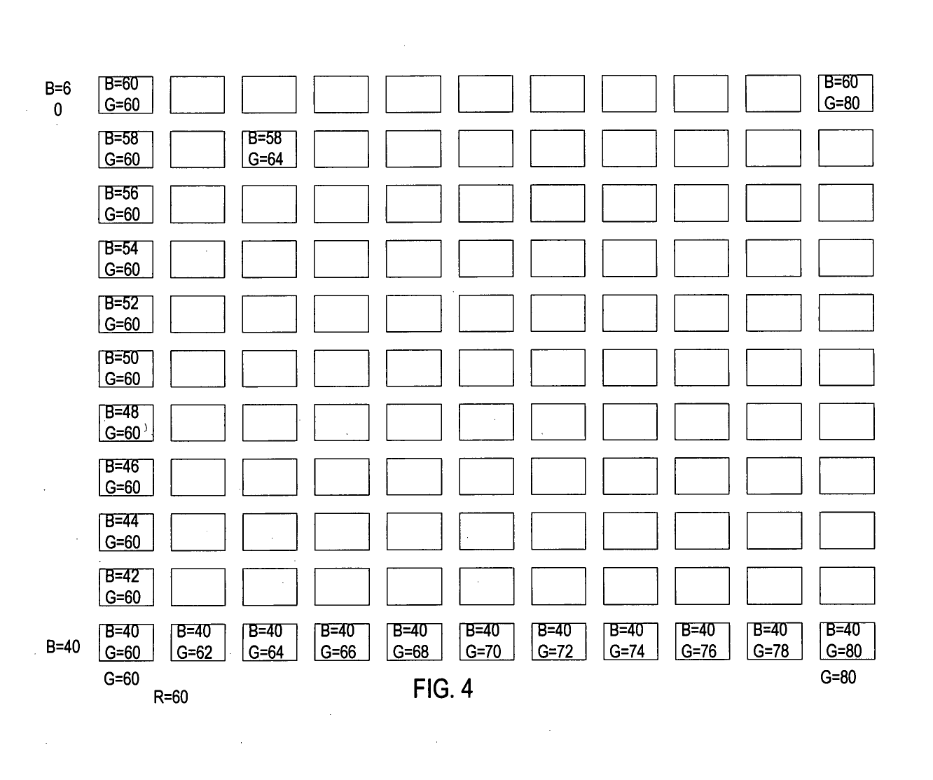

For example, assume that a user selects a closest color match from the first set of color samples that has RGB component amounts of R=60, G=70, B=50 (on a 0-100% scale). Assume that a selected desired color spacing is 2%. In such a case, a portion of a second set of color samples that will be subsequently printed may be such as illustrated in FIG. 4. In particular, the color samples illustrated in FIG. 4 represent points in a portion of a plane of the RGB color space having a fixed red component of 60%, with 2% spacings between the green and blue components. Specifically, the green component is varied between 60 and 80% at 2% intervals, and the blue component is varied between 40 and 60% at 2% intervals. The second set of color samples in this example would then include ten other sheets similar to that illustrated in FIG. 4, but wherein in each sheet the red component would have a different values including 50%, 52%, 54%, 56%, 58%, 62%, 64%, 66%, 68%, and 70%.

The user then selects another best match at step 34, and the steps 35, 36, 38 are repeated if necessary.

Clearly, other embodiments could include color samples spaced in a different manner, including different color spacing values, or color spacing values that are different for one or more of the colors, for both the first and subsequent sets of color samples. For example, in one embodiment color samples are printed in a CMYK color space. Color spacing values can be selected for each color (cyan, magenta, yellow and black) individually. In another embodiment, the color spacing of black is selected to be different than the color spacing of the other colors in the same space.

The advantages of a system and method such as that described is that a user is allowed to zoom in on an appropriate target color through successive iterations without having to print a very large number of color samples. Various features and advantages of the invention are set forth in the following claims.

What is claimed is:

1. A system for printing color samples in a desired color space to match a user selected target color, the system comprising:
a printer for printing sets of color samples and including a controller configured to generate instructions for printing a first set of color samples such that the samples in the first set have a first color spacing and define a first volume in the color space and configured to generate instructions for printing a subsequent set of color samples according to user selections; and
a user interface for communicating user selections to the printer, wherein the user selections include a closest match to the target color selected from a prior set of printed color samples and a desired color spacing of samples in a subsequent set,
wherein the printer prints a subsequent set of color samples according to the user selections until an acceptable match to the target color is achieved.

2. The system of claim 1, wherein the desired color spacing of samples includes different spacings for different colors in the color space.

3. The system of claim 1, wherein the user selections also include a desired volume in the color space for the subsequent set of color samples.

4. The system of claim 1, wherein the user interface is an operator panel of the printer.

5. The system of claim 1, wherein the user interface is remote from the printer.

6. The system of claim 1, wherein the color space is RGB color space.

7. The system of claim 6, wherein the printer prints with cyan, magneta, yellow and black colors and the controller performs color transforms to relate the RGB color space to the printed colors.

8. The system of claim 1, wherein the color space is selectable via the user interface.

9. The system of claim 1, wherein the printer prints with cyan, magenta, yellow and black colors, and the color space is CMYK color space.

10. The system of claim 9, wherein the color spacing of black can be selected to be different than the color spacing of the other colors in the color space.

11. The system of claim 1, further wherein the printer stores printer color levels corresponding to the acceptable match.

12. In a printer, a method of matching a target color, comprising:
generating in a controller printing instructions for the printer regarding printing sets of color samples, including the color spacing of the samples and the volume of the samples in a selected color space;
printing a first set of color samples;
selecting a color sample from the printed first set as the closest match to the target color,
communicating information relating to the selected color sample to the controller along with a desired color spacing of samples for a second set of color samples;
printing a second set of color samples having the desired color spacing and that spans a smaller volume in the color space than the first set; and
if necessary, printing one or more additional sets of color samples spanning successively smaller volumes in the color space, under the control of the controller, until a color sample in a successive set acceptably matches the target color.

13. The method of claim 12, wherein the desired color spacing of samples in the second set includes different spacings for different colors in the color space.

14. The method of claim 12, wherein information relating to the selected color sample is entered by user selection.

15. The method of claim 12, wherein a desired volume in the color space of the second set of color samples is entered by user selection.

16. The method of claim 12, wherein the color space is RGB color space.

17. The method of claim 12, wherein the color space is CMYK color space.

18. The method of claim 16, further comprising selecting the color space via a user interface.

19. The method of claim 12, wherein the printer prints with cyan, magenta, yellow and black colors, and the color space is CMYK color space.

20. The method of claim 12, further comprising storing printer color levels associated with the acceptable color sample.

21. The method of claim 12, wherein the printing of the first set of color samples includes printing of information related to the first set of color samples.

22. The method of claim 21, wherein the information related to the first set of color samples is the RGB component amounts of the first set of color samples.
